(19) United States
(12) Patent Application Publication
(10) Pub. No.: US 2017/0148503 A1
(43) Pub. Date: May 25, 2017

(54) DYNAMIC RANDOM ACCESS MEMORY CIRCUIT AND VOLTAGE CONTROLLING METHOD THEREOF

(71) Applicant: NANYA TECHNOLOGY CORPORATION, Taoyuan City (TW)

(72) Inventors: Ting-Shuo HSU, New Taipei City (TW); Chih-Jen CHEN, Kaohsiung City (TW)

(21) Appl. No.: 14/949,857

(22) Filed: Nov. 23, 2015

(51) Int. Cl. G11C 11/406; G11C 11/4096; G11C 11/4091

(52) U.S. Cl. CPC G11C 11/40615; G11C 11/4091; G11C 11/4096

(57) ABSTRACT

A dynamic random access memory circuit includes several memory cells, several word line drivers and a first voltage generator. The first voltage generator electrically coupled with the word line drivers, and the first voltage generator is configured to generate a first voltage signal to the word line drivers, in which during a self refresh period of the memory cells, the first voltage signal is decreased by the first voltage generator from a first level to a second level.

### BACKGROUND

Technical field

The present disclosure relates to a dynamic random access memory circuit and a voltage controlling method thereof. More particularly, the present disclosure relates to a dynamic random access memory circuit, which can reduce power consumption of memory cells during a self refresh period, and a voltage controlling method thereof.

Description of Related Art

With the advantages including low cost and high density, the dynamic random access memory circuit (DRAM) is widely used in electronic devices (e.g., laptop computers, tablet computers and smart phones). However, DRAM must be refreshed frequently, hundreds of times per second, in order to maintain the data stored in it. Consequently, additional power consumption is required in the electronic devices disposed with DRAM modules.

In order to meet the requirement of low power consumption for mobile devices, it is very important in this area to reduce the power consumption of DRAM modules.

### SUMMARY

The following presents a simplified summary of the disclosure in order to provide a basic understanding to the reader. This summary is not an extensive overview of the disclosure and it does not identify key/critical components of the present disclosure or delineate the scope of the present disclosure. Its sole purpose is to present some concepts disclosed herein in a simplified form as a prelude to the more detailed description that is presented later.

In one aspect, the present disclosure is to provide a dynamic random access memory circuit. The dynamic random access memory circuit includes several memory cells, several word line drivers and a first voltage generator. The first voltage generator electrically coupled with the word line drivers, and the first voltage generator is configured to generate a first voltage signal to the word line drivers, in which during a self refresh period of the memory cells, the first voltage signal is decreased by the first voltage generator from a first level to a second level.

In another aspect, the present disclosure is to provide a voltage controlling method suitable for a dynamic random access memory circuit, which includes several memory cells and several word line drivers. The voltage controlling method includes the following steps: generating a first voltage signal to the word line drivers; and decreasing the first voltage signal from a first level to a second level during a self refresh period of the memory cells.

By applying the techniques disclosed in the present disclosure, the power consumption of the dynamic random access memory circuit can be reduced.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic diagram of a dynamic random access memory circuit in accordance with one embodiment of the present disclosure;

FIG. 2 is a schematic diagram of the dynamic random access memory circuit depicted in FIG. 1;

FIG. 3 is a schematic diagram of a dynamic random access memory circuit in accordance with one embodiment of the present disclosure; and

FIG. 4 is a flow chart of a voltage controlling method in accordance with one embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description and claims, the terms “coupled” and “connected”, along with their derivatives, may be used. In particular embodiments, “connected” and “coupled” may be used to indicate that two or more elements are in direct physical or electrical contact with each other, or may also mean that two or more elements may be in indirect contact with each other. “Coupled” and “connected” may still be used to indicate that two or more elements cooperate or interact with each other.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

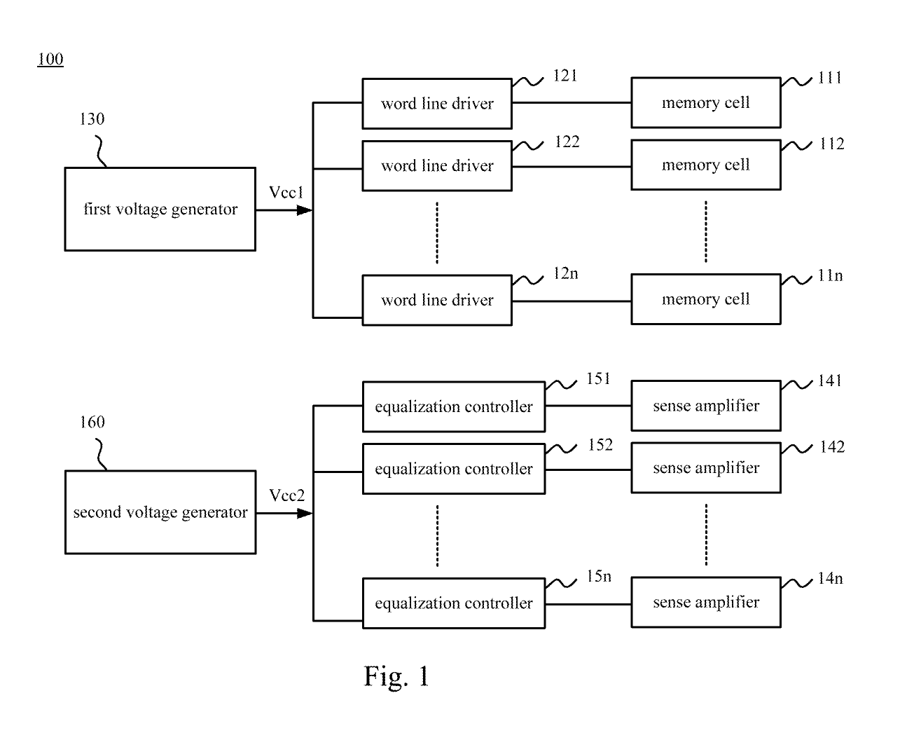

Reference is made first to FIG. 1. FIG. 1 is a schematic diagram of a dynamic random access memory circuit 100 in accordance with one embodiment of the present disclosure. According to one embodiment of the present disclosure, the dynamic random access memory circuit 100 is disposed within a DRAM module (not depicted). The dynamic random access memory circuit 100 includes memory cells 111-11n, word line drivers 121-12n, a first voltage generator 130, sense amplifiers 141-14n, equalization controllers 151-15n and a second voltage generator 160. As shown in FIG. 1, the word line drivers 121-12n are electrically coupled with the memory cells 111-11n respectively, and the first voltage generator 130 is electrically coupled with the word line drivers 121-12n. The equalization controllers 151-15n are electrically coupled with the sense amplifiers 141-14n respectively, and the second voltage generator 160 electrically coupled with the equalization controllers 151-15n.

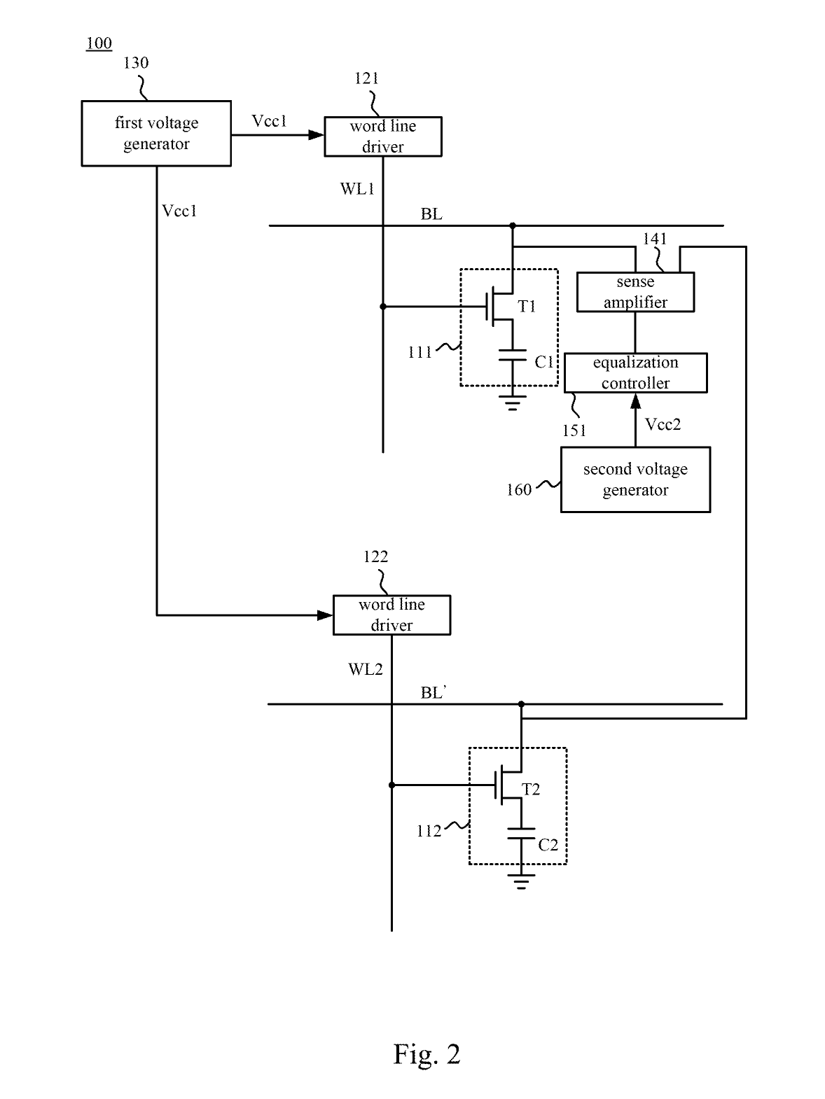

In this embodiment, each of the memory cells 111-11n is configured to store a data signal, and the first voltage generator 130 is configured to generate a first voltage signal Vcc1 to the word line drivers 121-12n. Each of the sense amplifiers 141-14n is configured to amplify a voltage difference between bit lines BL and /BL′ (will be shown in FIG. 2) for reading and writing the data signal into the memory cells 111-11n during a self refresh period of the memory cells, and each of the equalization controllers 151-15n is configured to provide a second voltage signal Vcc2 to each of the sense amplifiers 141-14n and equalize the bit lines BL and BL′ to same voltage level after reading and writing each data signal into the memory cells 111-11n during the self refresh period of the memory cells. That is to say, each data signal previously stored in each of the memory cells 111-11n is read and written into the same memory cell during the self refresh period. For further explanation, reference is made to FIG. 2.

FIG. 2 is a schematic diagram of the dynamic random access memory circuit 100 depicted in FIG. 1. In FIG. 2, the diagram depicts two of the memory cells (the memory cell 111 and 112), two of the word line drivers (the word line driver 121 and 122), one of the sense amplifiers (the sense amplifier 141), and one of the equalization controllers (the equalization controller 151), but all the other elements depicted in FIG. 1 can be similar to the description of FIG. 2 as following. As shown in FIG. 2, the memory cell 111 includes a transistor T1 and a storage capacitor C1 and the memory cell 112 includes a transistor T2 and a storage capacitor C2. The transistor T1 is electrically coupled with a bit line BL and a word line WL1, the transistor T1 is configured to transfer a data signal from the bit line BL to the storage capacitor C1 through the transistor T1 in accordance with a driving signal transmitted from the word line driver 121. The transistor T2 is electrically coupled with a bit line BL′ and a word line WL2, the transistor T2 is configured to transfer a data signal from the bit line BL′ to the storage capacitor C2 through the transistor T2 in accordance with a driving signal transmitted from the word line driver 122. The sense amplifier 141 is electrically coupled with the bit line BL, and the equalization controller 151 is configured to transmit the second voltage signal Vcc2 from the second voltage generator 160 to the sense amplifier 141. The sense amplifier 141 is configured to amplify a voltage difference between the bit lines BL and BL′ for reading and writing the data signal into the memory cell 111 during the self refresh period of the memory cell 111. After reading and writing the data signal into the memory cell 111, the equalization controller 151 will equalize the bit lines BL and BL′ to same voltage level. This rewriting mechanism helps the storage capacitor C1 and C2 in the memory cell 111 and 112 keep the correct value of the data signal continuously. The first voltage generator 130 is configured to generate a first voltage signal Vcc1 to the word line driver 121. In this embodiment, during the self refresh period, the first voltage signal Vcc1 is decreased by the first voltage generator 130 from a first level to a second level. For example, the first level is 3V and the second level is 2.8V, and the first voltage generator 130 will decrease the first voltage signal Vcc1 from the first level (3V) to the second level (2.8V) during the self refresh period. Consequently, the power consumption of the memory cells in the self refresh period can be reduced. It should be noted that, the abovementioned examples are just utilized for explanation, and the present disclosure is not limited in this regard.

In some embodiments, the second voltage Vcc2 is also decreased by the second voltage generator 160 from a third level to a fourth level during the self refresh period. For example, the third level is 1.5V and the fourth level is 1.4V, and the second voltage generator 160 will decrease the second voltage signal Vcc2 from the third level (1.5V) to the fourth level (1.4V) during the self refresh period. Consequently, the power consumption of the memory cells in the self refresh period can be reduced. In some embodiments, a first ratio of the first level to the second level is the same as a second ratio of the third level to the fourth level. For example, the first level is 3V, the second level is 2.8 V, the third level is 1.5V, and the fourth level is 1.4V, and thus the first ratio of the first level to the second level (3/2.8) is the same as the second ration of the third level to the fourth level (1.5/1.4). In some embodiments, the third level is a half of the first level, and the fourth level is a half of the second level. For example, the first level is 3V, the second level is 2.8 V, the third level is 1.5V, and the fourth level is 1.4V, and thus the third level (1.5V) is a half of the first level (3V), and the fourth level (1.4V) is a half of the second level (2.8V). It should be noted that, the abovementioned examples are just utilized for explanation, and the present disclosure is not limited in this regard.

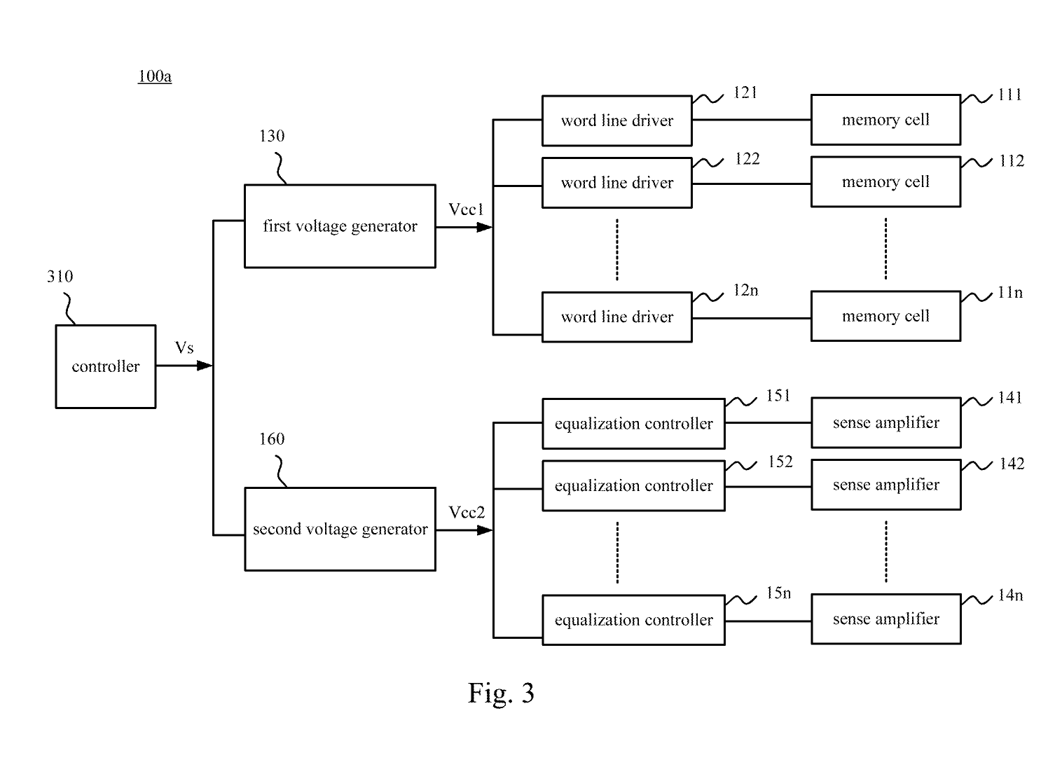

In some embodiments, the dynamic random access memory circuit 100 shown in FIG. 1 further includes a controller 310, as shown in FIG. 3. FIG. 3 is a schematic diagram of a dynamic random access memory circuit 100a in accordance with one embodiment of the present disclosure. The controller 310 is electrically coupled with the first voltage generator 130, and the controller 310 is configured to generate a control signal Vs to the first voltage generator 130 and the second voltage generator 160, in which the control signal Vs is enabled during the self refresh period. In this embodiment, the first voltage generator 130 and the second voltage generator 160 will decrease the first voltage signal Vcc1 from the first level to the second level and decrease the second voltage signal Vcc2 from the third level to the fourth level respectively while the voltage generator 130 and the second voltage generator 160 receive the enabled control signal Vs during the self refresh period. Consequently, the power consumption of the memory cells in the self refresh period can be reduced.

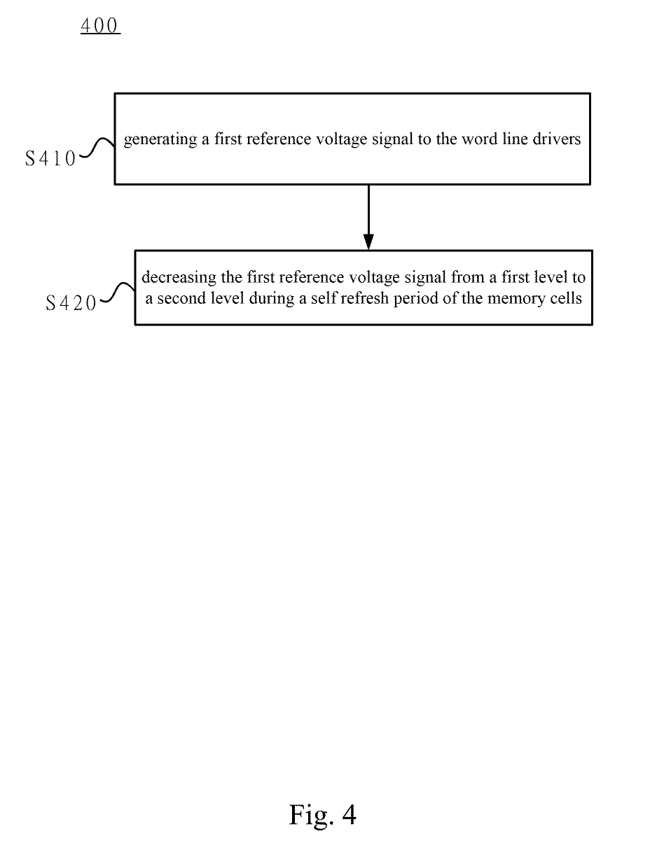

Reference is now made to FIG. 4. FIG. 4 is a flow chart of a voltage controlling method 400 in accordance with one embodiment of the present disclosure. The voltage controlling method 400 may be implemented by the dynamic random access memory circuit 100 illustrated in FIG. 1 and FIG. 2, or be implemented by the dynamic random access memory circuit 100a illustrated in FIG. 3, but is not limited in this regard. For convenience and clarity, it is assumed that the voltage controlling method 400 is implemented by the dynamic random access memory circuit 100 illustrated in FIG. 1.

The voltage controlling method 400 first conducts step 410: generating a first voltage signal to the word line drivers.

Then the voltage controlling method 400 conducts step 420, decreasing the first voltage signal from a first level to a second level during a self refresh period of the memory cells. Consequently, the power consumption of the memory cells in the self refresh period can be reduced.

In some embodiments, the voltage controlling method 400 further includes conducting step 430 (not depicted): generating a second voltage signal to the equalization controllers.

Then the voltage controlling method 400 conducts step 440 (not depicted): decreasing the second voltage signal from a third level to a fourth level during the self refresh period of the memory cells.

The above illustrations include exemplary operations, but the operations are not necessarily performed in the order shown. Operations may be added, replaced, changed order, and/or eliminated as appropriate, in accordance with the spirit and scope of various embodiments of the present disclosure.

By applying the techniques disclosed in the present disclosure, the power consumption of the dynamic random access memory circuit can be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A dynamic random access memory circuit comprising:
a plurality of memory cell
a plurality of word line drivers electrically coupled with the memory cells respectively:
a first voltage generator electrically coupled with the word line drivers, the first voltage generator being configured to generate a first voltage signal to the word line drivers,
a plurality of sense amplifiers;
a plurality of equalization controllers electrically coupled with the sense amplifiers respectively; and
a second voltage generator electrically coupled with the equalization controllers, the second voltage generator being configured to generate the second voltage signal to the equalization controllers,
wherein during the self refresh period of the memory cells, the second voltage signal is decreased by the second voltage generator from a third level to a fourth level, and the equalization controllers transmit the second voltage signal from the second voltage generator to each of the sense amplifiers,
wherein each of the memory cells is configured to store a data signal, and during a self refresh period of the memory cells, the first voltage signal is decreased by the first voltage generator from a first level to a second level and each data signal previously stored in each of the memory cells is read and written into the same memory cell; and,
wherein each of the equalization controllers is configured to provide a second voltage signal to each of the sense amplifiers and equalizes two bit lines of two of the memory cells to same voltage level after reading and writing the data signal into the same memory cell.

2-3. (canceled)

4. The dynamic random access memory circuit of claim 1, wherein each of the sense amplifiers is configured to amplify a voltage difference between the two bit lines for reading and writing the data signal into the memory cells during the self refresh period of the memory cells.

5. The dynamic random access memory circuit of claim 1, further comprising:
a controller electrically coupled with the first voltage generator, the controller being configured to generate control signal to the first voltage generator and the second voltage generator, wherein the control signal is enabled during the self refresh period of the memory cells.

6. A voltage controlling method, suitable for a dynamic random access memory circuit comprising a plurality of memory cells, a plurality of word line drivers, a plurality of sense amplifiers and a plurality of equalization controllers, the voltage controlling method comprises:
using a first voltage generator for generating a first voltage signal to the word line drivers;
decreasing the first voltage signal from a first level to a second level during a self refresh period of the memory cells;
storing a data signal in each of the memory cells; and
reading and writing the data signal previously stored in each of the memory cells into the same memory cell during the self refresh period;
using second voltage generator for generating a second voltage signal to the equalization controllers, so that the equalization controllers transmit the second voltage signal from the second voltage generator to each of the sense amplifiers;
decreasing the second voltage signal from a third level to a fourth level during the self refresh period of the memory cells
equalizing two bit lines of two of the memory cells to same voltage level after reading and writing the data signal into the same memory cell.

7-8. (canceled)

9. The voltage controlling method of claim 6, further comprising:
amplifying a voltage difference between the t pro bit lines for reading and writing the data signal into the memory cells during the self refresh period of the memory cells.
